(19) United States
(12) Patent Application Publication
(10) Pub. No.: US 2024/0136289 A1
(43) Pub. Date: Apr. 25, 2024

(54) VIRTUAL POWER SUPPLY THROUGH WAFER BACKSIDE

(71) Applicant: International Business Machines Corporation, Armonk, NY (US)

(72) Inventors: Rajiv Joshi, Yorktown Heights, NY (US); Ruilong Xie, Niskayuna, NY (US)

(21) Appl. No.: 18/049,301

(22) Filed: Oct. 24, 2022

(51) Int. Cl. H01L 23/528; H01L 21/768

(52) U.S. Cl. CPC H01L 23/5286; H01L 21/768

(57) ABSTRACT

Embodiments of the present invention are directed to processing methods and resulting structures for providing a virtual power supply through a wafer backside. In a non-limiting embodiment of the invention, a front end of line structure having a gate is formed and a back end of line structure is formed on a first surface of the front end of line structure. A backside power delivery network is formed on a second surface of the front end of line structure opposite the first surface. Source and drain regions on a first side of the gate are connected to the backside power delivery network and source and drain regions on a second side of the gate are connected to the back end of line structure.

### BACKGROUND

The present invention generally relates to fabrication methods and resulting structures for semiconductor devices, and more specifically, to processing methods and resulting structures for providing a virtual power supply through a wafer backside.

The development of an integrated circuit (i.e., chip) involves several stages from design through fabrication. Many aspects of the development are performed iteratively to ensure that the chip ultimately manufactured meets all design requirements. Defining the chip architecture is one of the earliest phases of integrated circuit development. The power (e.g., power requirement), performance (e.g., timing), and area (i.e., space needed) for the resulting chip, collectively PPA, is one of the primary metrics by which integrated circuits are evaluated. PPA is largely a consequence of the chip architecture.

Semiconductor fabrication continues to evolve towards improving one or more aspects of PPA. For example, a higher number of active devices (mainly transistors) of ever decreasing device dimensions are placed on a given surface of semiconductor material. Density scaling has put a strain on the design and fabrication of the interconnects between the front end of line of the integrated circuit, consisting mainly of the active devices, and the contact terminals of the integrated circuit. In many chip architectures, all of these interconnects are incorporated in the back end of line (BEOL) structure of the integrated circuit, which includes a stack of metallization layers and vertical via connections built on top of the front end of line (FEOL) structure.

A key component of the BEOL structure is the power delivery network (PDN). The PDN of an integrated circuit is defined by the conductors and vias connected to the power supply (VDD) and ground (VSS) terminals of the chip. The PDN is responsible for delivering power to the individual devices in the front end. The integration of the PDN in the BEOL has become particularly challenging as device densities continue to scale. Backside power delivery is one known solution to this problem, and involves moving some (or most, or all) layers of the PDN from the front side of the integrated circuit to the back side. In a backside-style architecture, the repositioned layers are not formed on top of the FEOL, but are instead formed on the opposite side of the chip (i.e., on the backside of the semiconductor substrate onto which the active devices have been built).

### SUMMARY

Embodiments of the invention are directed to a method for providing a virtual power supply through a wafer backside. A non-limiting example of the method includes forming a front end of line structure having a gate and forming a back end of line structure on a first surface of the front end of line structure. A backside power delivery network is formed on a second surface of the front end of line structure opposite the first surface. Source and drain regions on a first side of the gate are connected to the backside power delivery network and source and drain regions on a second side of the gate are connected to the back end of line structure.

Embodiments of the invention are directed to a semiconductor structure. A non-limiting example of the semiconductor structure includes a front end of line structure having a gate and a back end of line structure on a first surface of the front end of line structure. A backside power delivery network is positioned on a second surface of the front end of line structure opposite the first surface. Source and drain regions on a first side of the gate are connected to the backside power delivery network and source and drain regions on a second side of the gate are connected to the back end of line structure.

Embodiments of the invention are directed to a semiconductor structure. A non-limiting example of the semiconductor structure includes a front end of line structure having a gate and a back end of line structure on a first surface of the front end of line structure. A backside power delivery network is positioned on a second surface of the front end of line structure opposite the first surface. Source and drain regions on a first side of the gate are connected to a power supply in the backside power delivery network and source and drain regions on a second side of the gate are connected to a virtual power supply in the backside power delivery network.

Additional technical features and benefits are realized through the techniques of the present invention. Embodiments and aspects of the invention are described in detail herein and are considered a part of the claimed subject matter. For a better understanding, refer to the detailed description and to the drawings.

### BRIEF DESCRIPTION OF THE DRAWINGS

The specifics of the exclusive rights described herein are particularly pointed out and distinctly claimed in the claims at the conclusion of the specification. The foregoing and other features and advantages of the embodiments of the invention are apparent from the following detailed description taken in conjunction with the accompanying drawings in which:

FIG. 1A depicts a cross-sectional view taken along the line X (across gate in channel of logic region) in FIG. 1F of a semiconductor wafer after an initial set of processing operations according to one or more embodiments of the invention;

FIG. 1B depicts a cross-sectional view taken along the line Y1 (along gate in source/drain of logic region) in FIG. 1F of the semiconductor wafer after the initial set of processing operations according to one or more embodiments of the invention;

FIG. 1C depicts a cross-sectional view taken along the line Y2 (along gate in first source/drain of boost region) in FIG. 1F of the semiconductor wafer after the initial set of processing operations according to one or more embodiments of the invention;

FIG. 1D depicts a cross-sectional view taken along the line Y3 (along gate in channel of boost region) in FIG. 1F of the semiconductor wafer after the initial set of processing operations according to one or more embodiments of the invention;

FIG. 1E depicts a cross-sectional view taken along the line Y4 (along gate in second source/drain of boost region) in FIG. 1F of the semiconductor wafer after the initial set of processing operations according to one or more embodiments of the invention;

FIG. 1F depicts a top-down reference view of the semiconductor wafer;

FIG. 2A depicts the cross-sectional view taken along the line X after a processing operation according to one or more embodiments of the invention;

FIG. 2B depicts the cross-sectional view taken along the line Y1 after a processing operation according to one or more embodiments of the invention;

FIG. 2C depicts the cross-sectional view taken along the line Y2 after a processing operation according to one or more embodiments of the invention;

FIG. 2D depicts the cross-sectional view taken along the line Y3 after a processing operation according to one or more embodiments of the invention;

FIG. 2E depicts the cross-sectional view taken along the line Y3 after a processing operation according to one or more embodiments of the invention;

FIG. 2F depicts a top-down reference view of the semiconductor wafer;

FIG. 3A depicts the cross-sectional view taken along the line X after a processing operation according to one or more embodiments of the invention;

FIG. 3B depicts the cross-sectional view taken along the line Y1 after a processing operation according to one or more embodiments of the invention;

FIG. 3C depicts the cross-sectional view taken along the line Y2 after a processing operation according to one or more embodiments of the invention;

FIG. 3D depicts the cross-sectional view taken along the line Y3 after a processing operation according to one or more embodiments of the invention;

FIG. 3E depicts the cross-sectional view taken along the line Y3 after a processing operation according to one or more embodiments of the invention;

FIG. 3F depicts a top-down reference view of the semiconductor wafer;

FIG. 4A depicts the cross-sectional view taken along the line X after a processing operation according to one or more embodiments of the invention;

FIG. 4B depicts the cross-sectional view taken along the line Y1 after a processing operation according to one or more embodiments of the invention;

FIG. 4C depicts the cross-sectional view taken along the line Y2 after a processing operation according to one or more embodiments of the invention;

FIG. 4D depicts the cross-sectional view taken along the line Y3 after a processing operation according to one or more embodiments of the invention;

FIG. 4E depicts the cross-sectional view taken along the line Y3 after a processing operation according to one or more embodiments of the invention;

FIG. 4F depicts a top-down reference view of the semiconductor wafer;

FIG. 5A depicts the cross-sectional view taken along the line X after a processing operation according to one or more embodiments of the invention;

FIG. 5B depicts the cross-sectional view taken along the line Y1 after a processing operation according to one or more embodiments of the invention;

FIG. 5C depicts the cross-sectional view taken along the line Y2 after a processing operation according to one or more embodiments of the invention;

FIG. 5D depicts the cross-sectional view taken along the line Y3 after a processing operation according to one or more embodiments of the invention;

FIG. 5E depicts the cross-sectional view taken along the line Y3 after a processing operation according to one or more embodiments of the invention;

FIG. 5F depicts a top-down reference view of the semiconductor wafer;

FIG. 6A depicts a cross-sectional view taken along the line X after an alternative processing operation according to one or more embodiments of the invention;

FIG. 6B depicts the cross-sectional view taken along the line Y1 after the alternative processing operation according to one or more embodiments of the invention;

FIG. 6C depicts the cross-sectional view taken along the line Y2 after the alternative processing operation according to one or more embodiments of the invention;

FIG. 6D depicts the cross-sectional view taken along the line Y3 after the alternative processing operation according to one or more embodiments of the invention;

FIG. 6E depicts the cross-sectional view taken along the line Y3 after the alternative processing operation according to one or more embodiments of the invention;

FIG. 6F depicts a top-down reference view of the semiconductor wafer;

FIG. 7A depicts a cross-sectional view taken along the line X after yet another alternative processing operation according to one or more embodiments of the invention;

FIG. 7B depicts the cross-sectional view taken along the line Y1 after the alternative processing operation according to one or more embodiments of the invention;

FIG. 7C depicts the cross-sectional view taken along the line Y2 after the alternative processing operation according to one or more embodiments of the invention;

FIG. 7D depicts the cross-sectional view taken along the line Y3 after the alternative processing operation according to one or more embodiments of the invention;

FIG. 7E depicts the cross-sectional view taken along the line Y3 after the alternative processing operation according to one or more embodiments of the invention;

FIG. 7F depicts a top-down reference view of the semiconductor wafer; and

FIG. 8 depicts a flow diagram illustrating a method according to one or more embodiments of the invention.

The diagrams depicted herein are illustrative. There can be many variations to the diagram or the operations described therein without departing from the spirit of the invention. For instance, the actions can be performed in a differing order or actions can be added, deleted or modified.

In the accompanying figures and following detailed description of the described embodiments of the invention, the various elements illustrated in the figures are provided with two or three-digit reference numbers. With minor exceptions, the leftmost digit(s) of each reference number correspond to the figure in which its element is first illustrated.

### DETAILED DESCRIPTION

It is understood in advance that although example embodiments of the invention are described in connection with a particular transistor architecture, embodiments of the invention are not limited to the particular transistor architectures or materials described in this specification. Rather, embodiments of the present invention are capable of being implemented in conjunction with any other type of transistor architecture or materials now known or later developed.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to an overview of technologies that are more specifically relevant to aspects of the present invention, ICs are fabricated in a series of stages, including a front-end-of-line (FEOL) stage, a middle-of-line (MOL) stage, and a back-end-of-line (BEOL) stage. The process flows for fabricating modern ICs are often identified based on whether the process flows fall in the FEOL stage, the MOL stage, or the BEOL stage. Generally, the FEOL stage is where device elements (e.g., transistors, capacitors, resistors, etc.) are patterned in the semiconductor substrate/wafer. The FEOL stage processes include wafer preparation, isolation, gate patterning, and the formation of wells, source/drain (S/D) regions, extension junctions, silicide regions, and liners. The MOL stage typically includes process flows for forming the contacts (e.g., CA) and other structures that communicatively couple to active regions (e.g., gate, source, and drain) of the device element. For example, the silicidation of source/drain regions, as well as the deposition of metal contacts, can occur during the MOL stage to connect the elements patterned during the FEOL stage. Layers of interconnections (e.g., metallization layers) are formed above these logical and functional layers during the BEOL stage to complete the IC. Most ICs need more than one layer of wires to form all the necessary connections, and as many as 5-12 layers are added in the BEOL process. The various BEOL layers are interconnected by vias that couple from one layer to another. Insulating dielectric materials are used throughout the layers of an IC to perform a variety of functions, including stabilizing the IC structure and providing electrical isolation of the IC elements. For example, the metal interconnecting wires in the BEOL region of the IC are isolated by dielectric layers to prevent the wires from creating a short circuit with other metal layers.

As discussed previously, a key component of the BEOL structure is the power delivery network (PDN). Backside power delivery (also referred to as a backside power delivery network) is a chip architecture that involves repositioning layers of the PDN from the top of the FEOL to the opposite side of the chip. In other words, in a backside-style architecture the PDN layers are placed on the backside of the semiconductor substrate onto which the active devices have been built. Challenges remain, however, in fully leveraging backside power delivery chip architectures.

One such challenge is the difficulty in co-integrating backside power delivery with a virtual power supply (sometimes referred to as boost). “Virtual” power supplies, as the name suggests, are not connected to the actual device power supply (e.g., a common supply voltage, often denoted VDD), but instead serve as separate, supplemental supplies of power (boost) to specific regions of a substrate (i.e., some transistor(s)). Device boosting is an attractive technology offering that exploits on-chip capacitive coupling (e.g., between interconnect lines in SOI finFETs) to enable dynamically boosted power delivery. Boosting can improve device functionality and performance by allowing, for example, increases in individual transistor voltages (e.g., from 0.3 v to 0.7 v, etc.). Virtual power supplies are not easily co-integrated with backside power delivery chip architectures as both platforms require dedicated metallization systems (interconnects).

Turning now to an overview of aspects of the present invention, one or more embodiments of the invention address the above-described shortcomings by providing fabrication methods and resulting structures for providing a virtual power supply through a wafer backside (sometimes referred to as the backside virtual power supply). As used herein, a “backside virtual power supply” refers to a structural feature of one or more embodiments of this disclosure where virtual power is interdigitated with boost signal lines at the backside of a wafer, thereby reducing a number of metallization levels over the FEOL devices (e.g., transistor arrays).

Boosted devices (e.g., transistors) can be connected to the backside virtual power supply in a variety of ways. In some embodiments, one side of the source/drain regions of a boosted device is connected to a frontside power supply (VDD) in the BEOL metallization (Mx layer), while the other side of the source/drain is connected to a virtual power supply at the backside of the wafer. A gate can be connected to a boost signal on the frontside and a backside boost signal line can run in parallel to the virtual power supply lines connected to the gate.

While generally described with respect to a backside virtual power supply, in some embodiments, the virtual power supply and true power supply can backside-frontside swapped. For example, in some embodiments, one side of the source/drain regions of a boosted device is connected to a backside power deliver network (BS-PDN), while the other side of the source/drain is connected to a virtual power supply at the frontside of the wafer. The gate of the boosted device can be connected to a boost signal on the frontside.

In yet other embodiments, the virtual power supply and true power supply can run in parallel on the backside (or frontside). For example, one side of the source/drain regions of a boosted device is connected to a backside power deliver network (BS-PDN) and the other side of the source/drain is connected to a virtual power supply at the backside side of the wafer. The gate can be connected to a boost signal on the frontside and a backside boost signal line can run in parallel to the virtual power supply lines connected to the gate.

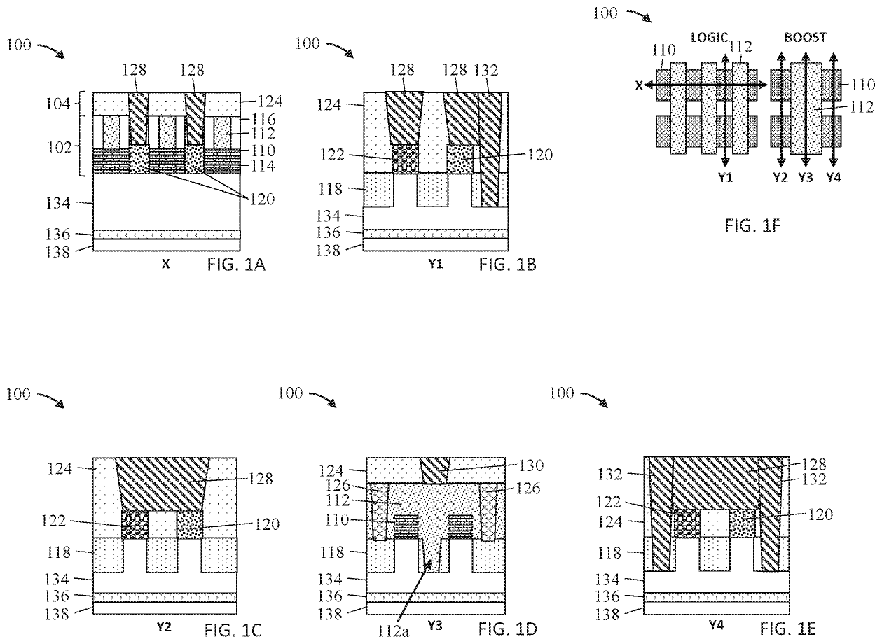

Turning now to a more detailed description of fabrication operations and resulting structures according to aspects of the invention, FIG. 1A depicts a cross-sectional view taken along the line X (across gate in channel of logic region) in FIG. 1F of a semiconductor wafer 100 after an initial set of fabrication operations have been applied as part of a method of fabricating a final semiconductor device according to one or more embodiments of the invention. FIG. 1B depicts a cross-sectional view taken along the line Y1 (along gate in source/drain of logic region) in FIG. 1F. FIG. 1C depicts a cross-sectional view taken along the line Y2 (along gate in first source/drain of boost region) in FIG. 1F. FIG. 1D depicts a cross-sectional view taken along the line Y3 (along gate in channel of boost region) in FIG. 1F. FIG. 1E depicts a cross-sectional view taken along the line Y4 (along gate in second source/drain of boost region) in FIG. 1F. FIG. 1F depicts a top-down reference view of the semiconductor wafer 100.

As shown in FIGS. 1A-1F, various FEOL 102 and MOL 104 structures have been built in the semiconductor wafer 100. The specific examples of the FEOL 102 and MOL 104 are provided for ease of discussion only and are not meant to be particularly limited. For example, the FEOL 102 illustrates a nanosheet-style transistor architecture. It should be understood, however, that the nanosheet-style transistor architecture of the FEOL 102 is provided for ease of discussion only and that other transistor architectures (e.g., vertical tunneling transistors, planar transistors, finFETs, etc.) are included in the contemplated scope of this disclosure. Similarly, other MOL structures can be fabricated depending on the needs of a given application, and all such configurations are within the contemplated scope of this disclosure.

In some embodiments, the semiconductor wafer 100 includes one or more nanosheets 110 (collectively, a nanosheet stack(s)) and a gate 112 formed over channel regions of the one or more nanosheets 110. As used herein, a “channel region” refers to the portion of a nanosheet of the one or more nanosheets 110 over which the gate 112 is formed, and through which current passes from source to drain in the final device.

The semiconductor wafer 100 can include various additional FEOL structures, such as, for example, inner spacers 114, gate spacers 116, a shallow trench isolation (STI) region 118, first S/D regions 120, second S/D regions 122, interlayer dielectrics 124, and gate cut 126, and MOL structures, such as, for example, contacts and vias (e.g., S/D contacts 128, gate contacts 130, via-to-backside power rail 132 (VBPRs), etc.), configured and arranged as shown.

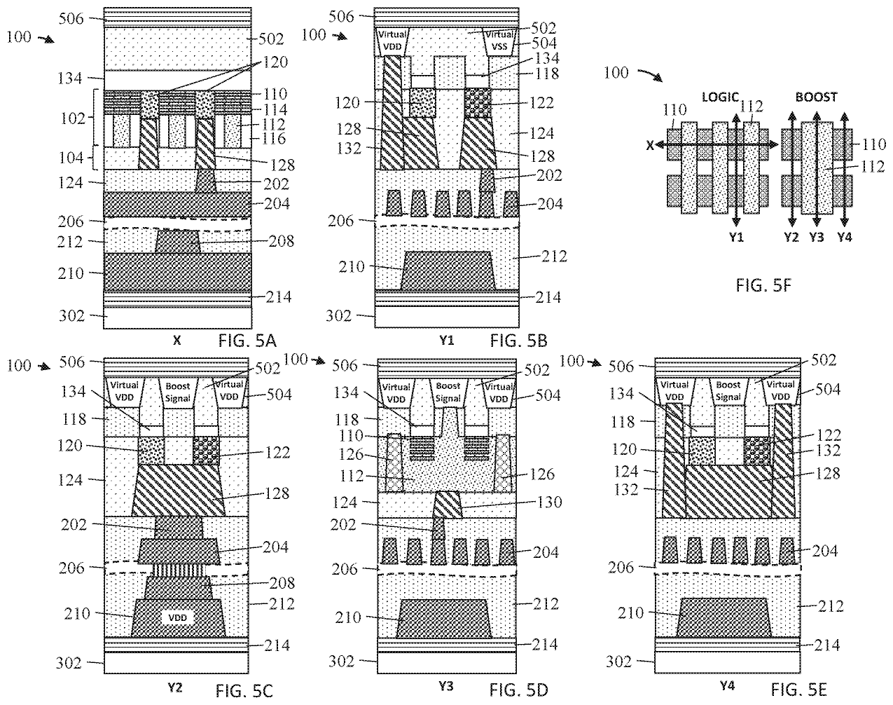

In some embodiments, the gate 112 includes a gate extension 112a. As discussed in further detail with respect to FIG. 5D, the gate extension 112a extends into the STI region 118 to enable a backside signal connection.

In some embodiments, the semiconductor wafer 100 includes a substrate 138 having an etch stop layer 136 (e.g., a buried oxide layer or a SiGe epi layer) and an additional semiconductor layer 134 (e.g., Si) over the etch stop layer 136, although other substrate configurations are within the contemplated scope of this disclosure. In some embodiments, the substrate (e.g., substrate 134/136/138) includes a silicon-on-insulator (an) structure and the substrate 138 is a bottommost substrate layer.

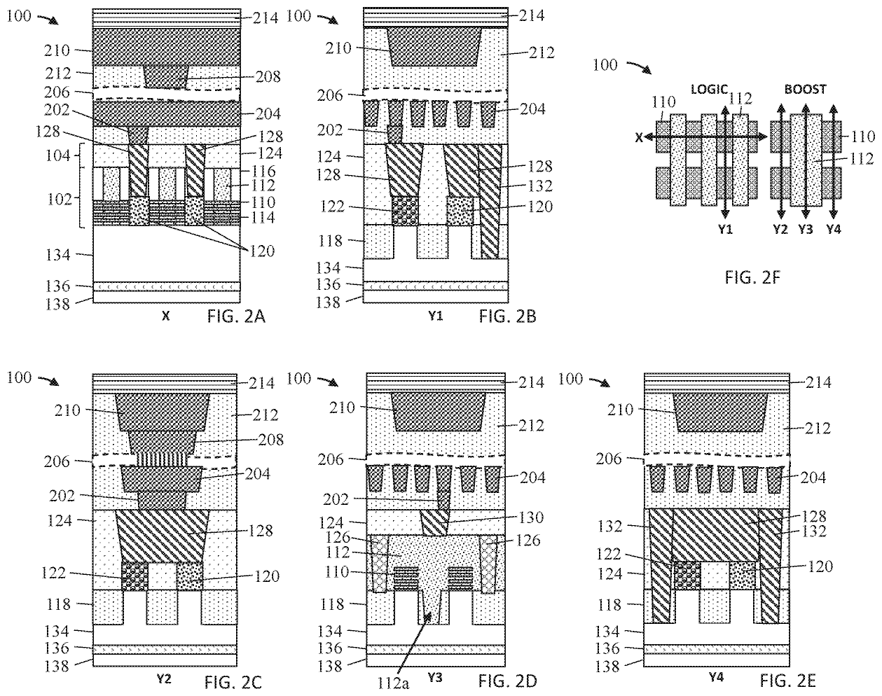

FIGS. 2A, 2B, 2C, 2D, and 2E depict cross-sectional views of the semiconductor wafer 100 taken along the lines X, Y1, Y2, Y3, and Y4, respectively, of FIG. 2F after a processing operation according to one or more embodiments. In some embodiments, BEOL structures are built on the semiconductor wafer 100. The specific examples of the BEOL structures are provided for ease of discussion only and are not meant to be particularly limited. For example, the BEOL structure shown in FIG. 2A can include one or more first vias 202 (“V0”), a first metal layer 204 (“M1”), any number of intermediate interconnects 206 (metal levels/vias between Mx and M1 which connects a power supply (“VDD”) at Mx to M1), one or more last vias 208 (“Vx−1”), a last metal layer 210 (“Mx”), and one or more dielectric layers 212. In some embodiments, one or more additional BEOL levels 214 are formed above the last metal layer 210.

As shown in FIG. 2D, the gate 112 is connected to the one or more first vias 202 by way of the gate contact 130. In some embodiments, the gate contact 130 is configured as a boost signal in boost regions of the semiconductor wafer 100 (refer to FIG. 2F). Boost circuit regions refer to regions of the semiconductor wafer 100 where the power supply (“VDD”) in Mx is converted to a virtual VDD at the wafer backside according to one or more embodiments.

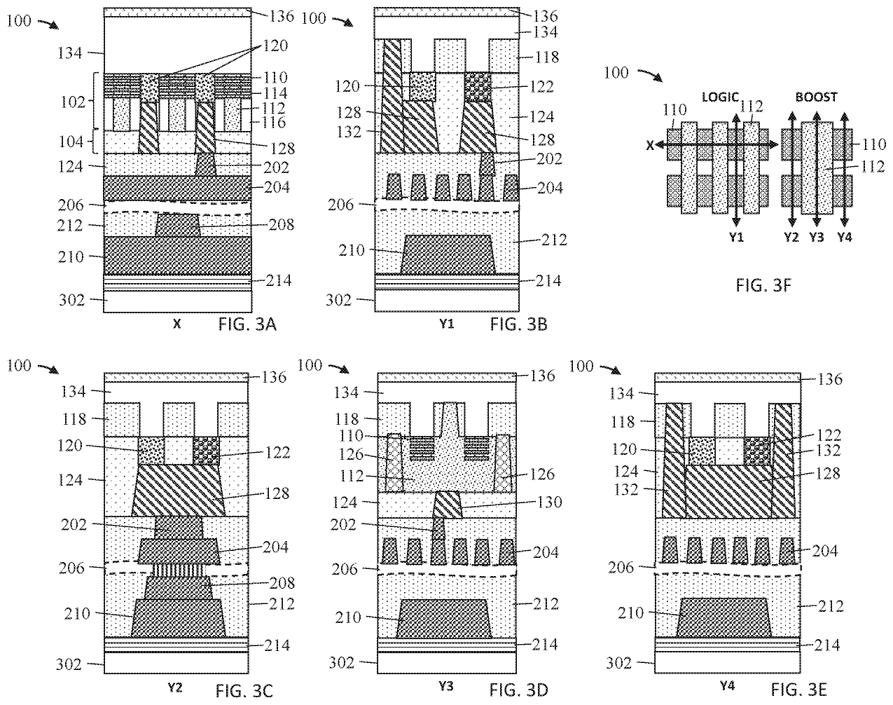

FIGS. 3A, 3B, 3C, 3D, and 3E depict cross-sectional views of the semiconductor wafer 100 taken along the lines X, Y1, Y2, Y3, and Y4, respectively, of FIG. 3F after a processing operation according to one or more embodiments. In some embodiments, a carrier wafer 302 is formed over the last metal layer 210 (e.g., on the one or more additional BEOL levels 214, if present).

In some embodiments, the semiconductor wafer 100 is flipped and the bottommost substrate layer 138 is removed. The bottommost substrate layer 138 can be removed using any suitable process, such as, for example, combination of wafer grinding, CMP, dry etch and a wet etch stopping on the etch stop layer 136.

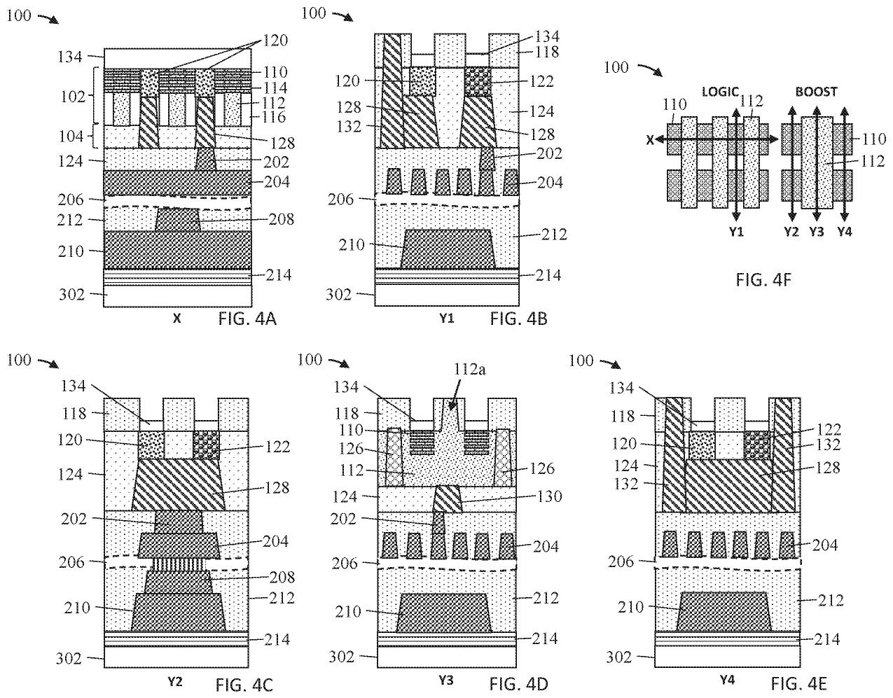

FIGS. 4A, 4B, 4C, 4D, and 4E depict cross-sectional views of the semiconductor wafer 100 taken along the lines X, Y1, Y2, Y3, and Y4, respectively, of FIG. 4F after a processing operation according to one or more embodiments. In some embodiments, the etch stop layer 136 is removed and the additional semiconductor layer 134 is recessed to expose a top surface of the STI region 118 (FIGS. 4B, 4C, 4D, 4E), the gate extension 112a (FIG. 4D), and the VBPRs 132 (FIGS. 4B, 4E).

The etch stop layer 136 can be removed and the additional semiconductor layer 134 can be recessed using any suitable technique, such as, for example, using a wet etch, a dry etch, or a combination of sequential wet and/or dry etches. In some embodiments, the additional semiconductor layer 134 can be recessed below the top surface of the STI region 118, the gate extension 112a, and/or the VBPRs 132.

FIGS. 5A, 5B, 5C, 5D, and 5E depict cross-sectional views of the semiconductor wafer 100 taken along the lines X, Y1, Y2, Y3, and Y4, respectively, of FIG. 5F after a processing operation according to one or more embodiments. In some embodiments, a backside dielectric 502 is formed on the semiconductor wafer 100. In some embodiments, the backside dielectric 502 is deposited or otherwise formed on the recessed surface of the additional semiconductor layer 134.

In some embodiments, the backside dielectric 502 is a high-k dielectric. As used herein, a “high-k” dielectric refers to a material having a dielectric constant greater than 3.0 (i.e., a higher dielectric constant than conventional BEOL low-k dielectrics). Examples of high-k materials include, but are not limited to, SiO2, SiN, SiC, SiOC, or combination of above materials.

In some embodiments, conductive materials are deposited in the backside dielectric 502 to define one or more backside metallization layers (here, the backside metal layer 504). The backside metal layer 504 can also be referred to as the backside M1. This process can be referred to as a backside M1 metallization (or, as a first backside metallization layer). The backside metal layer 504 can include various lines and vias depending on the requirements of a given application. In some embodiments, the backside metal layer 504 is configured as a backside virtual power supply including a “virtual VDD”, a “virtual VSS”, and a “boost signal” (as shown). In some embodiments, the frontside metallization layers (e.g., the last metal layer 210) are configured as a frontside power supply include a “VDD” (as shown) and “VSS” (not separately shown).

In some embodiments, a backside power delivery network (BS-PDN) 506 is formed over the backside metal layer 504. The BS-PDN 506 can include any number of metal layers, lines, and vias, and can be formed in a similar manner as the BEOL structures discussed previously with respect to FIGS. 2A, 2B, 2C, 2D, and 2E, except that the BS-PDN 506 is formed on an opposite side of the semiconductor wafer 100.

After backside M1 metallization is complete, the semiconductor wafer 100 can be finalized using known processes (e.g., additional BEOL, far back end of line (FBEOL), packaging, etc., processes used to define a final device, including the incorporation of additional frontside or backside metallization layers).

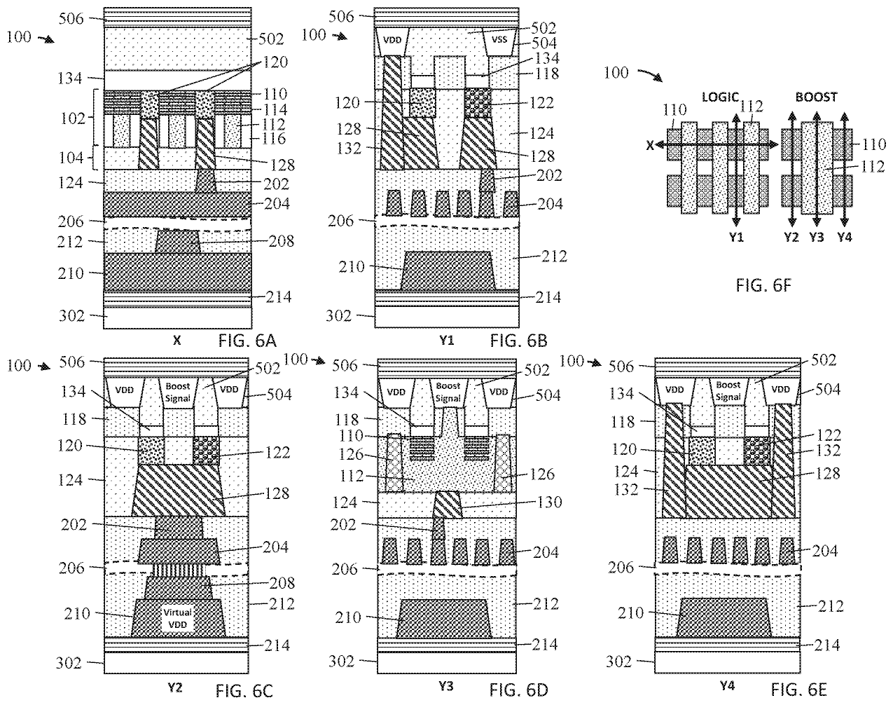

FIGS. 6A, 6B, 6C, 6D, and 6E depict cross-sectional views of the semiconductor wafer 100 taken along the lines X, Y1, Y2, Y3, and Y4, respectively, of FIG. 6F after a processing operation according to one or more embodiments. FIGS. 6A, 6B, 6C, 6D, and 6E depict an alternative embodiment from that shown in FIGS. 5A, 5B, 5C, 5D, and 5E. In FIGS. 5A, 5B, 5C, 5D, and 5E, the backside power delivery is fully virtual, while the frontside power delivery is the true power supply. In contrast, in FIGS. 6A, 6B, 6C, 6D, and 6E the backside power delivery is the true power supply, while the frontside power delivery is virtual. The semiconductor wafer 100 is otherwise configured in a similar manner as shown in FIGS. 5A, 5B, 5C, 5D, and 5E.

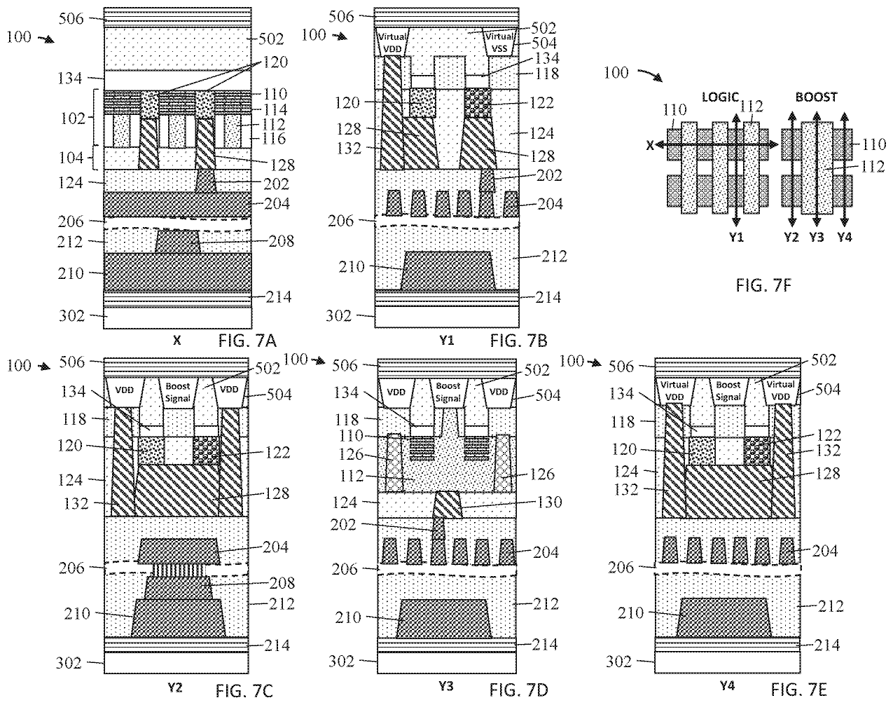

FIGS. 7A, 7B, 7C, 7D, and 7E depict cross-sectional views of the semiconductor wafer 100 taken along the lines X, Y1, Y2, Y3, and Y4, respectively, of FIG. 7F after a processing operation according to one or more embodiments. FIGS. 7A, 7B, 7C, 7D, and 7E depict an alternative embodiment from that shown in FIGS. 5A, 5B, 5C, 5D, and 5E. In FIGS. 5A, 5B, 5C, 5D, and 5E, the backside power delivery is fully virtual, while the frontside power delivery is the true power supply. In contrast, in FIGS. 7A, 7B, 7C, 7D, and 7E the backside power delivery offers both the true power supply and virtual power (i.e., a hybrid backside power delivery system).

In some embodiments, additional VBPRs 132 are provided for backside power delivery (see FIG. 7C). In some embodiments, one or more first vias 202 are removed (or their fabrication is entirely skipped), preventing a frontside-to-backside short due to the presence of the additional VBPRs 132. The semiconductor wafer 100 is otherwise configured in a similar manner as shown in FIGS. 5A, 5B, 5C, 5D, and 5E.

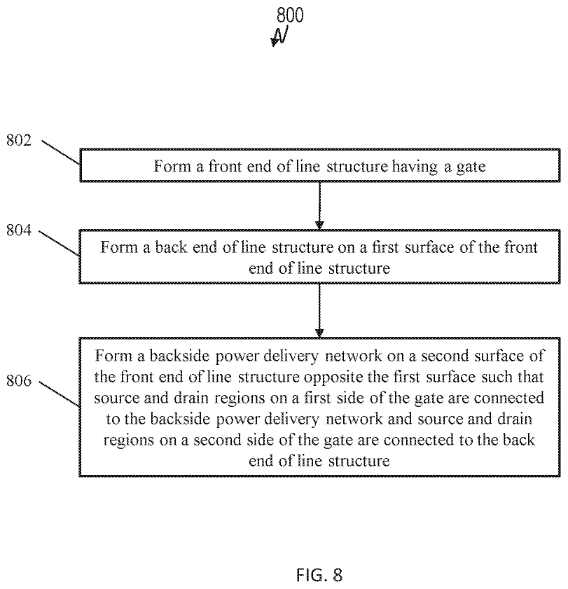

FIG. 8 depicts a flow diagram illustrating a method 800 for providing a virtual power supply through a wafer backside according to one or more embodiments of the invention. As shown at block 802, a front end of line structure including a gate is formed. At block 804, a back end of line structure is formed on a first surface of the front end of line structure. At block 806, a backside power delivery network is formed on a second surface of the front end of line structure opposite the first surface.

In some embodiments, source and drain regions on a first side of the gate are connected to the backside power delivery network and source and drain regions on a second side of the gate are connected to the back end of line structure.

In some embodiments, the back end of line structure includes a power supply. In some embodiments, a virtual power supply is formed between the front end of line structure and the backside power delivery network. In some embodiments, the power supply is connected to the source and drain regions on the second side of the gate and the virtual power supply is connected to the source and drain regions on the first side of the gate.

In some embodiments, the back end of line structure includes a virtual power supply. In some embodiments, a power supply is formed between the front end of line structure and the backside power delivery network. In some embodiments, the power supply is connected to the source and drain regions on the first side of the gate and the virtual power supply is connected to the source and drain regions on the second side of the gate.

In some embodiments, the gate is connected to a boost signal on the back end of line structure and a backside boost signal line between the backside power delivery network and the front end of line structure. In some embodiments, the gate includes a gate extension that extends through a shallow trench isolation region of the front end of line structure. In some embodiments, the gate extension is directly connected to the backside boost signal line.

The methods and resulting structures described herein can be used in the fabrication of IC chips. The resulting IC chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes IC chips, ranging from toys and other low-end applications to advanced computer products having a display, a keyboard or other input device, and a central processor.

Various embodiments of the present invention are described herein with reference to the related drawings. Alternative embodiments can be devised without departing from the scope of this invention. Although various connections and positional relationships (e.g., over, below, adjacent, etc.) are set forth between elements in the following description and in the drawings, persons skilled in the art will recognize that many of the positional relationships described herein are orientation-independent when the described functionality is maintained even though the orientation is changed. These connections and/or positional relationships, unless specified otherwise, can be direct or indirect, and the present invention is not intended to be limiting in this respect. Similarly, the term “coupled” and variations thereof describes having a communications path between two elements and does not imply a direct connection between the elements with no intervening elements/connections between them. All of these variations are considered a part of the specification. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

Additionally, the term “exemplary” is used herein to mean “serving as an example, instance or illustration.” Any embodiment or design described herein as “exemplary” is not necessarily to be construed as preferred or advantageous over other embodiments or designs. The terms “at least one” and “one or more” are understood to include any integer number greater than or equal to one, i.e. one, two, three, four, etc. The terms “a plurality” are understood to include any integer number greater than or equal to two, i.e. two, three, four, five, etc. The term “connection” can include an indirect “connection” and a direct “connection.”

References in the specification to “one embodiment,” “an embodiment,” “an example embodiment,” etc., indicate that the embodiment described can include a particular feature, structure, or characteristic, but every embodiment may or may not include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

Spatially relative terms, e.g., “beneath,” “below,” “lower,” “above,” “upper,” and the like, are used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device can be otherwise oriented (e.g., rotated 90 degrees or at other orientations), and the spatially relative descriptors used herein should be interpreted accordingly.

The terms “about,” “substantially,” “approximately,” and variations thereof, are intended to include the degree of error associated with measurement of the particular quantity based upon the equipment available at the time of filing the application. For example, “about” can include a range of ±8% or 5%, or 2% of a given value.

The phrase “selective to,” such as, for example, “a first element selective to a second element,” means that the first element can be etched and the second element can act as an etch stop (i.e., the second element remains).

The term “conformal” (e.g., a conformal layer or a conformal deposition) means that the thickness of the layer is substantially the same on all surfaces, or that the thickness variation is less than 15% of the nominal thickness of the layer.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases can be controlled and the system parameters can be set so that the depositing atoms arrive at the deposition surface of the semiconductor substrate with sufficient energy to move about on the surface such that the depositing atoms orient themselves to the crystal arrangement of the atoms of the deposition surface. An epitaxially grown semiconductor material can have substantially the same crystalline characteristics as the deposition surface on which the epitaxially grown material is formed. For example, an epitaxially grown semiconductor material deposited on a <100> orientated crystalline surface can take on a <100> orientation. In some embodiments of the invention of the invention, epitaxial growth and/or deposition processes can be selective to forming on semiconductor surface, and may or may not deposit material on other exposed surfaces, such as silicon dioxide or silicon nitride surfaces.

As used herein, “p-type” refers to the addition of impurities to an intrinsic semiconductor that creates deficiencies of valence electrons. In a silicon-containing substrate, examples of p-type dopants, i.e., impurities, include but are not limited to, boron, aluminum, gallium, and indium.

As used herein, “n-type” refers to the addition of impurities that contributes free electrons to an intrinsic semiconductor. In a silicon containing substrate examples of n-type dopants, i.e., impurities, include but are not limited to antimony, arsenic and phosphorous.

As previously noted herein, for the sake of brevity, conventional techniques related to semiconductor device and integrated circuit (IC) fabrication may or may not be described in detail herein. By way of background, however, a more general description of the semiconductor device fabrication processes that can be utilized in implementing one or more embodiments of the present invention will now be provided. Although specific fabrication operations used in implementing one or more embodiments of the present invention can be individually known, the described combination of operations and/or resulting structures of the present invention are unique. Thus, the unique combination of the operations described in connection with the fabrication of a semiconductor device according to the present invention utilize a variety of individually known physical and chemical processes performed on a semiconductor (e.g., silicon) substrate, some of which are described in the immediately following paragraphs.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), chemical-mechanical planarization (CMP), and the like. Reactive ion etching (RIE), for example, is a type of dry etching that uses chemically reactive plasma to remove a material, such as a masked pattern of semiconductor material, by exposing the material to a bombardment of ions that dislodge portions of the material from the exposed surface. The plasma is typically generated under low pressure (vacuum) by an electromagnetic field. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

The flowchart and block diagrams in the Figures illustrate possible implementations of fabrication and/or operation methods according to various embodiments of the present invention. Various functions/operations of the method are represented in the flow diagram by blocks. In some alternative implementations, the functions noted in the blocks can occur out of the order noted in the Figures. For example, two blocks shown in succession can, in fact, be executed substantially concurrently, or the blocks can sometimes be executed in the reverse order, depending upon the functionality involved.

The descriptions of the various embodiments of the present invention have been presented for purposes of illustration, but are not intended to be exhaustive or limited to the embodiments described. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments described herein.

What is claimed is:

1. A method for forming a semiconductor device, the method comprising:
forming a front end of line structure comprising a gate;
forming a back end of line structure on a first surface of the front end of line structure; and
forming a backside power delivery network on a second surface of the front end of line structure opposite the first surface;
wherein source and drain regions on a first side of the gate are connected to the backside power delivery network and source and drain regions on a second side of the gate are connected to the back end of line structure.

2. The method of claim 1, wherein the back end of line structure comprises a power supply.

3. The method of claim 2, further comprising forming a virtual power supply between the front end of line structure and the backside power delivery network.

4. The method of claim 3, wherein the power supply is connected to the source and drain regions on the second side of the gate and the virtual power supply is connected to the source and drain regions on the first side of the gate.

5. The method of claim 1, wherein the back end of line structure comprises a virtual power supply.

6. The method of claim 5, further comprising forming a power supply between the front end of line structure and the backside power delivery network.

7. The method of claim 6, wherein the power supply is connected to the source and drain regions on the first side of the gate and the virtual power supply is connected to the source and drain regions on the second side of the gate.

8. The method of claim 1, wherein the gate is connected to a boost signal on the back end of line structure and a backside boost signal line between the backside power delivery network and the front end of line structure.

9. The method of claim 8, wherein the gate comprises a gate extension that extends through a shallow trench isolation region of the front end of line structure.

10. The method of claim 9, wherein the gate extension is directly connected to the backside boost signal line.

11. A semiconductor device comprising:
a front end of line structure comprising a gate;
a back end of line structure on a first surface of the front end of line structure; and
a backside power delivery network on a second surface of the front end of line structure opposite the first surface;
wherein source and drain regions on a first side of the gate are connected to the backside power delivery network and source and drain regions on a second side of the gate are connected to the back end of line structure.

12. The semiconductor device of claim 11, wherein the back end of line structure comprises a power supply.

13. The semiconductor device of claim 12, further comprising a virtual power supply between the front end of line structure and the backside power delivery network.

14. The semiconductor device of claim 13, wherein the power supply is connected to the source and drain regions on the second side of the gate and the virtual power supply is connected to the source and drain regions on the first side of the gate.

15. The semiconductor device of claim 11, wherein the back end of line structure comprises a virtual power supply.

16. The semiconductor device of claim 15, further comprising a power supply between the front end of line structure and the backside power delivery network.

17. The semiconductor device of claim 16, wherein the power supply is connected to the source and drain regions on the first side of the gate and the virtual power supply is connected to the source and drain regions on the second side of the gate.

18. The semiconductor device of claim 11, wherein the gate is connected to a boost signal on the back end of line structure and a backside boost signal line between the backside power delivery network and the front end of line structure.

19. A semiconductor device comprising:
a front end of line structure comprising a gate;
a back end of line structure on a first surface of the front end of line structure; and
a backside power delivery network on a second surface of the front end of line structure opposite the first surface;
wherein source and drain regions on a first side of the gate are connected to a power supply in the backside power delivery network and source and drain regions on a second side of the gate are connected to a virtual power supply in the backside power delivery network.

20. The semiconductor device of claim 19, wherein the gate is connected to a boost signal on the back end of line structure and a backside boost signal line between the backside power delivery network and the front end of line structure.
